(19) United States
(12) Patent Application Publication
(10) Pub. No.: US 2008/0176391 A1
(43) Pub. Date: Jul. 24, 2008

(54) METHOD FOR MANUFACTURING SEMICONDUCTOR DEVICE

(75) Inventors: Hirotaka MIYAMOTO, Toyama (JP); Akiyoshi TAMURA, Osaka (JP); Keiichi MURAYAMA, Toyama (JP); Kenichi MIYAJIMA, Toyama (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 12/018,454

(22) Filed: Jan. 23, 2008

(30) Foreign Application Priority Data
Jan. 24, 2007 (JP) 2007-014047

(51) Int. Cl. H01L 21/44

(52) U.S. Cl. 438/605; 257/E21.476

(57) ABSTRACT

The present invention has an object of providing a method for manufacturing a semiconductor device which can prevent occurrence of pattern abnormality of an electrode and deterioration of an electronic property. The method for manufacturing the semiconductor device including a GaAs substrate with a portion made of GaAs includes: forming a Ti/Pt/Au/Ti electrode on the GaAs substrate, the electrode including Pt and having a layered structure in which a top layer made of Ti; forming a collector electrode including AuGe on a portion made of GaAs; and performing heat treatment on the collector electrode in a state where both of the Ti/Pt/Au/Ti electrode and the collector electrode are exposed to a surface.

### BACKGROUND OF THE INVENTION

(1) Field of the Invention

The present invention relates to a manufacturing method which can prevent occurrence of pattern abnormality and deterioration of an electronic property in a semiconductor device operating in a high frequency band.

(2) Description of the Prior Art

Compared with silicon (Si) semiconductors, III-V compound semiconductors are characterized by their high electron mobility. Applying this characteristic, they are frequently used for devices for which a high speed operation or a highly efficient operation is required. Above all, a heterojunction bipolar transistor (HBT) where heterojunction is used for junction between emitter and base is characterized in that it excels in a high frequency characteristic, that it allows a signal amplification with low distortion, that it can be used with a single power supply, and so on, because a bandgap of an emitter layer is wider than that of a base layer on the HBT. Accordingly, the HBT has come to be widely used as a semiconductor component operating in a high frequency band, including a power amplifier for mobile phone.

In more recent years, further improvement of the high frequency characteristic has been required for the HBT so that it can be used not only as the power amplifier for mobile phone but also as a semiconductor component operating in a higher frequency band.

There is the maximum oscillation frequency (fmax) as an index for a feature of a power amplifier or the like used in the high frequency band. The higher this value is, the better an operation in the high frequency band is.

The fmax is defined by a relation of the following expression (1), and is obviously inversely proportional to a base-collector capacity Cbc. It should be noted that, in the formula (1), fT is a cutoff frequency and Rb is base resistance.

fmax=√{fT/(8π·Rb·Cbc)} (1)

The base-collector capacity Cbc is proportional to an area of a base mesa. What is generally known, as a method for improving the high frequency characteristic by reducing the Cbc, is a method for narrowing a width of an emitter electrode or a base electrode of a single HBT cell or for decreasing the area of the base mesa as much as possible through a means of electrode formation with the self-aligning method and so on.

FIGS. 1A to 1F are cross sections showing a method for manufacturing a conventional HBT (for example, refer to Japanese Unexamined Patent Application Laid-Open Publication No. 5-136159).

First, a GaAs substrate (GaAs wafer) is formed by sequentially epitaxial-growing a subcollector layer 2 made of GaAs, a collector layer 3 made of GaAs, a base layer 4 made of GaAs, and an emitter layer 5 made of InGaP or AlGaAs on a surface of a semi-insulating GaAs substrate 1. After that, an emitter mesa 10 is formed on the GaAs substrate with the photolithography method and the dry etching method, and further a base mesa 11 is formed in the same manner (FIG. 1A).

Next, an element isolation region 12 made of a high-resistivity layer is formed by performing ion implantation using a photoresist film for covering the emitter mesa 10 and the base mesa 11 as a mask, and a HBT unit cell region 9 (transistor region) is laid out. After that, a spacer film 13 made of a SiO₂ film is formed on the entire GaAs substrate (FIG. 1B).

Next, after a resist is patterned so that a hole opening is formed at a place where an emitter electrode 21 and a base electrode 22 are to be formed with the photolithography method, another hole opening is formed at the hole opening of the resist on the spacer film 13. Subsequently, after Ti/Pt/Au is made into a film with the vacuum evaporation method, the emitter electrode 21 and the base electrode 22 are formed with the lift-off method (FIG. 1C).

Next, concerning a place where a collector electrode 8 is to be formed, after a resist is patterned in the same manner so that a hole opening is formed, another hole opening is formed at the hole opening of the resist on the spacer film 13. Subsequently, after AuGe/Ni/Au is made into a film with the vacuum evaporation method, the collector electrode 8 is formed with the lift-off method (FIG. 1D).

Next, in a state where the emitter electrode 21, the base electrode 22, and the collector electrode 8 are not covered with an interlayer film respectively, that is, in a state where each of them is exposed to the surface, heat treatment at 380° C. for 90 seconds is performed on each of the electrodes.

Next, a SiN film is formed, as a first interlayer film 14, on the entire GaAs substrate with the plasma CVD method. Subsequently, an electrode-first wiring interlayer contact hole 15 is formed by removing, with the dry etching method, a part of the first interlayer film 14 where the emitter electrode 21, the base electrode 22, and collector electrode 8 are to be connected to a first wiring layer 16 (FIG. 1E).

Finally, the first wiring layer 16, a second interlayer film (not illustrated), a second wiring layer 17, and a final protective film (not illustrated) are formed at a predetermined place with the well-known method (FIG. 1F).

### SUMMARY OF THE INVENTION

In the conventional method for manufacturing the HBT shown in FIGS. 1A to 1F, it is necessary to perform heat treatment (alloy) at about 380° C. to form an ohmic contact between the subcollector layer 2 and the collector electrode 8 in the process of forming the collector electrode 8. However, since Ge of AuGe/Ni/Au layered as the collector electrode 8 and Ga included in the collector layer 3 and the subcollector layer 2 are bonded when performing the heat treatment, there is a case where excess As in the collector layer 3 and subcollector layer 2 frees from around the collector electrode 8 and is deposited on the emitter electrode 21 and the base electrode 22. Accordingly, not only does the pattern abnormality of electrode occur with respective surfaces of the emitter electrode 21 and the base emitter 22 being discolored, but also the deposited As passes through the respective top layers of the emitter electrode 21 and the base electrode 22 made of Ti/Pt/Au and is bonded to Pt. As a result, there is a problem that formation of a PtAs compound causes resistance of the electrode to rise considerably, thereby drastically deteriorating the electronic property, especially the RF property during the high frequency operation.

Furthermore, in the case where the same material as AuGe/Ni/Au making up the collector electrode 8 is used for a backside via hole stopper metal being formed on the chip having the HBT and the stopper metal is formed concurrently with the formation of the collector electrode 8, an area of AuGe/Ni/Au existing on the chip substantially increases compared to a case where other metal structure is used as the backside via hole stopper metal. Therefore, the above-mentioned deterioration of the RF property caused by depositing the freed As on the base electrode and the emitter electrode becomes remarkable.

The above-mentioned problem is described using the HBT as an example. However, as long as a semiconductor device has both the AuGe/Ni/Au electrode directly contacting GaAs and the Ti/Pt/Au electrode and performs the heat treatment in a state where both of the electrodes are not covered with the interlayer film, the same problem occurs even with other devices such as a field-effect transistor (FET).

The present invention has an object of providing a method for manufacturing a semiconductor device which prevents the occurrence of pattern abnormality of the electrode and the deterioration of the electronic property, so as to solve the above-mentioned problem.

In order to achieve the above-mentioned object, the method for manufacturing the semiconductor device of the present invention is a method for manufacturing a semiconductor device having a semiconductor substrate with a portion made of GaAs includes: forming the first electrode on the semiconductor substrate, the first electrode including Pt and having a layered structure in which the top layer is made of Ti; forming the second electrode including AuGe on a portion made of GaAs; and performing the heat treatment on the second electrode in a state where both of the first electrode and the second electrode are exposed to a surface.

Here, in the forming of the first electrode, it is preferable to form the first electrode having the top layer of Ti, the top layer having a film thickness between 5 nm and 15 nm inclusive.

Moreover, it is possible that the method for manufacturing the semiconductor device further includes: forming an interlayer film on both of the first electrode and the second electrode after performing the heat treatment; and removing a part of the interlayer film in order to connect both of the first electrode and the second electrode to a lead wiring. Further, in the removing, the top layer of Ti of the first electrode is removed concurrently with the removing of the part of the interlayer film.

In the conventional method for manufacturing the semiconductor device, when the heat treatment is performed on an electrode having Au as the top layer and including Pt such as Ti/Pt/Au and another electrode made of AuGe/Ni/Au or the like concurrently with the respective electrodes not being covered with the interlayer film, as mentioned above, the formation of the PtAs compound by the freed As causes sheet resistance of the electrode to rise substantially. However, according to the method for manufacturing the semiconductor device of the present invention, since an electrode having Ti as the top layer and made of Ti/Pt/Au/Ti or the like is used instead of the electrode having Au as the top and including Pt such as Ti/Pt/Au, Ti becomes a barrier metal, so that bonding of the freed As and Pt does not occur.

As described above, according to the method for manufacturing the semiconductor device of the present invention, since the formation of the PtAs compound by the freed As does not occur, there is an effect that the pattern abnormality of the electrode can be prevented.

In addition, according to the method for manufacturing the semiconductor device of the present invention, since the formation of the PtAs compound by the freed As does not occur, the sheet resistance of the electrode becomes almost constant in plane of a substrate and there is an effect that stable RF property can be obtained in the semiconductor device operating in the high frequency band.

Furthermore, according to the method for manufacturing the semiconductor device of the present invention, in comparison with the conventional method for manufacturing the semiconductor device, since there is no need for newly-required facilities and materials, there is an effect that the semiconductor device which prevents the pattern abnormality and the deterioration of the electronic property can be obtained in a concise procedure without additional costs.

### FURTHER INFORMATION ABOUT TECHNICAL BACKGROUND TO THIS APPLICATION

The disclosure of Japanese Patent Application No. 2007-014047 filed on Jan. 24, 2007 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings which illustrate a specific embodiment of the invention. In the Drawings:

FIGS. 1A to 1F are a cross section showing each process in a method for manufacturing a conventional HBT;

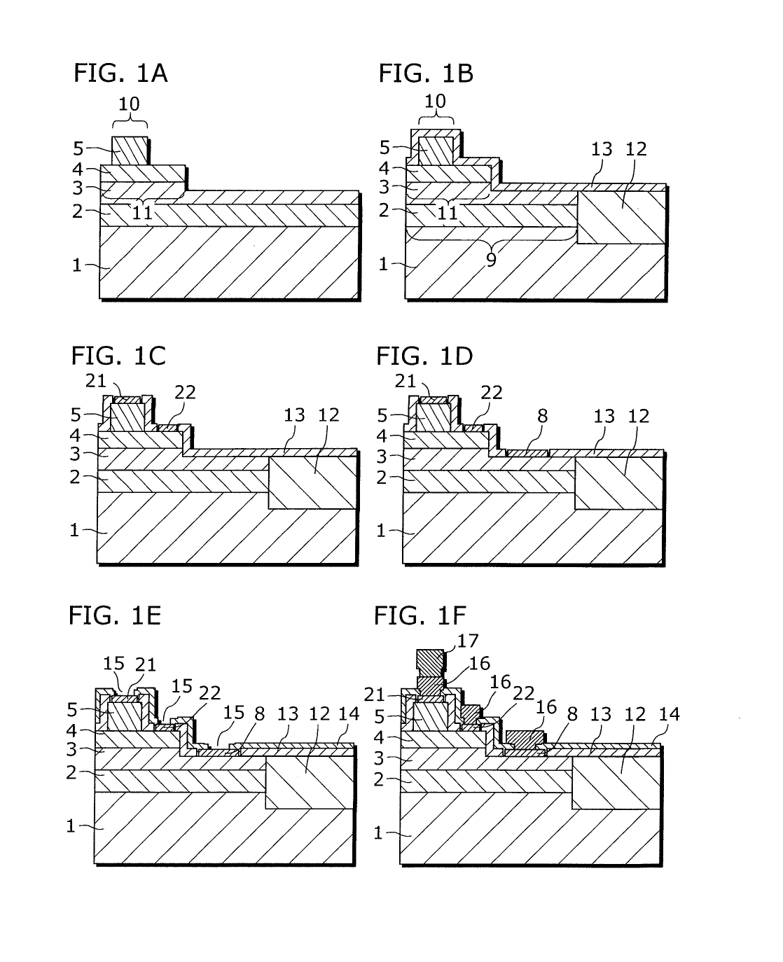

FIGS. 2A to 2F are a cross section showing each process in a method for manufacturing a HBT according to a first embodiment;

FIG. 3 is a diagram showing a relation between a Ti film thickness of the top layer of a Ti/Pt/Au/Ti electrode, layered, from the bottom, with Ti/Pt/Au/Ti, and contact resistance;

FIG. 4 is a diagram showing a relation between the Ti film thickness of the top layer of the Ti/Pt/Au/Ti electrode, layered, from the bottom, with Ti/Pt/Au/Ti, and a size of a electrode-first wiring interlayer contact hole formed on the Ti/Pt/Au/Ti electrode; and

FIGS. 5A to 5F are a cross section showing each process in a method for manufacturing a HBT according to a second embodiment.

### DESCRIPTION OF THE PREFERRED EMBODIMENT(S)

### First Embodiment

Hereinafter, a method for manufacturing a HBT according to a first embodiment of the present invention is described with reference to the drawings.

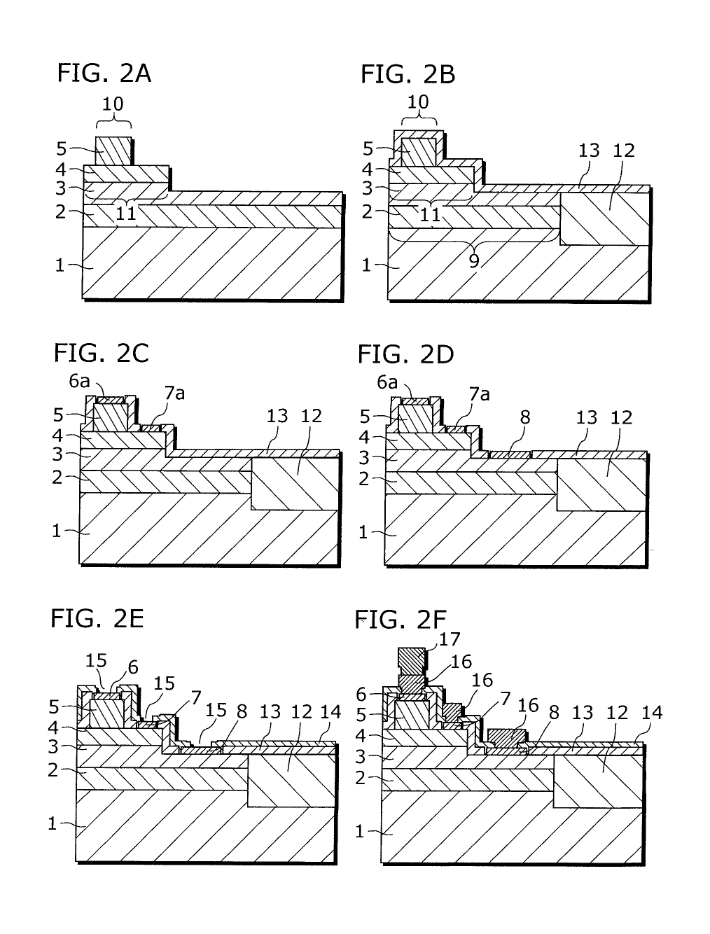

FIGS. 2A to 2F are a cross section showing each process in the method for manufacturing the HBT according to the first embodiment.

First, a GaAs substrate (GaAs wafer) is formed by sequentially epitaxial-growing a subcollector layer 2 made of GaAs, a collector layer 3 made of GaAs, a base layer 4 made of GaAs, and an emitter layer 5 made of InGaP on a surface of a semi-insulating GaAs substrate 1. After that, an emitter mesa 10 is formed on the GaAs substrate with the photolithography method and the dry etching method, and further a base mesa 11 is formed in the same manner (FIG. 2A).

Next, an element isolation region 12 made of a high-resistivity layer is formed by performing ion implantation using a photoresist film for covering the emitter mesa 10 and the base mesa 11 as a mask, and a HBT unit cell region 9 (transistor region) is laid out. After that, a spacer film 13 made of a SiO₂ film is formed on the entire GaAs substrate (FIG. 2B).

Next, after a resist is patterned so that a hole opening is to be formed at a place where Ti/Pt/Au/Ti electrodes 6a and 7a are formed with the photolithography method, another hole opening is formed at the hole opening of the resist on the exposed spacer film 13. Subsequently, after Ti/Pt/Au/Ti is made into a film with the vacuum evaporation method, the Ti/Pt/Au/Ti electrodes 6a and 6b which are layered, from the bottom, with Ti/Pt/Au/Ti are formed with the lift-off method (FIG. 2C).

Next, concerning a place where a collector electrode 8 is to be formed, after a resist is patterned in the same manner so that a hole opening is formed, another hole opening is formed at the hole opening of the resist on the exposed spacer film 13. Subsequently, after AuGe/Ni/Au is made into a film with the vacuum evaporation method, the collector electrode 8 which is layered, from the bottom, with AuGe/Ni/Au is formed with the lift-off method (FIG. 2D).

Next, in a state where the Ti/Pt/Au/Ti electrodes 6a, 7a, and the collector electrode 8 are not covered with an interlayer film respectively, that is, in a state where each of them is exposed to the surface, heat treatment at 380° C. for 90 seconds is performed on each of the electrodes. It should be noted that, from the point of view of suppressing free of As as much as possible and of reducing contact resistance among a base electrode, an emitter electrode, and a first wiring layer, in a processing of the heat treatment, as long as treatment temperature at a time of the heat treatment and a treatment time are optimized between 360° C. and 420° C. and between 15 seconds and 360 seconds respectively, the heat treatment condition may not be 380° C. and 90 seconds.

Next, a SiN film is formed, as a first interlayer film 14, on the entire GaAs substrate with the plasma CVD method. Subsequently, an electrode-first wiring interlayer contact hole 15 is formed by removing, with the dry etching method, a part of the first interlayer film 14 where the Ti/Pt/Au/Ti electrodes 6a and 7a and the collector electrode 8 to be are connected to a first wiring layer 16 as a lead wiring (FIG. 2E). A dry etching process condition in a process of forming the electrode-first wiring interlayer contact hole 15 is optimized, and Ti of the respective top layers of the Ti/Pt/Au/Ti electrodes 6a and 7a is also removed concurrently with the formation of the electrode-first wiring interlayer contact hole 15. Accordingly, an emitter electrode 6 and a base electrode 7 whose partial Ti of the respective top layers is removed so as to expose Au to a surface are formed, the emitter electrode 6 and the base electrode 7 being made of Ti/Pt/Au/Ti. As just described, the reason for removing partial Ti of the respective top layers is that when Ti is present at a place where the emitter electrode 6 and the base electrode 7 are connected to the first wiring layer 16, contact resistance among the base electrode 7, the emitter electrode 6, and the first wiring layer is caused to rise compared to a Ti/Pt/Au electrode.

Lastly, the first wiring layer 16, a second interlayer film (not illustrated), a second wiring layer 17, and a final protective film (not illustrated) are formed at a predetermined place with the well-known method (FIG. 2F).

It should be noted that, from the point of view of reducing the contact resistance among the base electrode 7, the emitter electrode 6, and the first wiring layer 16 and of size controllability of the electrode-first wiring interlayer contact hole 15, it is necessary to set, between 5 nm and 15 nm, a Ti film thickness of the respective top layers of the Ti/Pt/Au/Ti electrodes 6a and 7a. In the present embodiment, the Ti film thickness is assumed to be 10 nm.

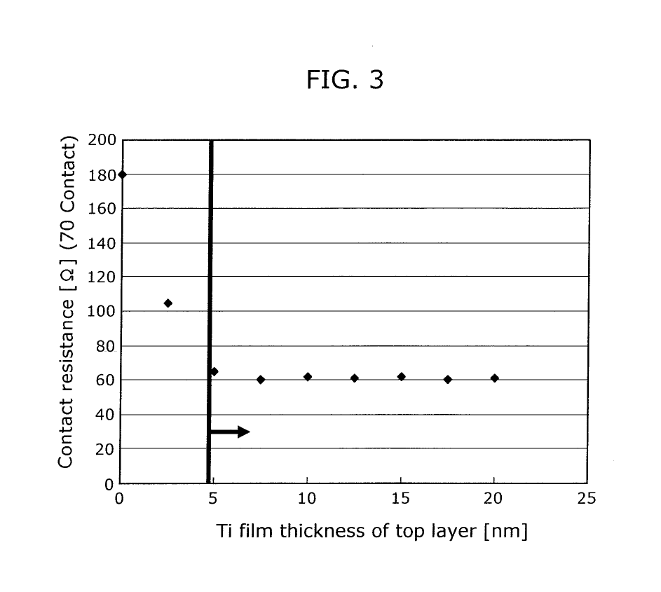

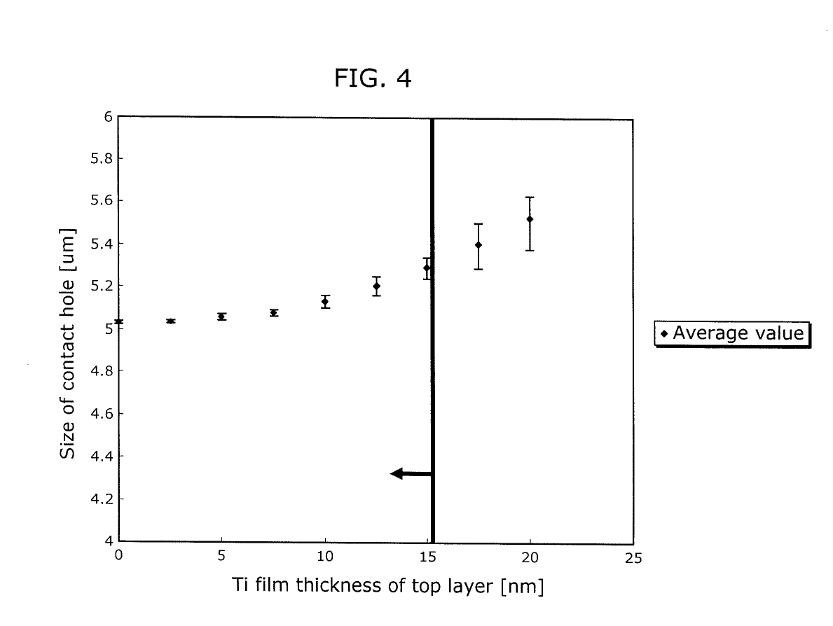

Just for reference, a graph describing a relation between the Ti film thickness of the respective top layers of the Ti/Pt/Au/Ti electrodes 6a and 7a and the contact resistance among the base electrode 7, the emitter electrode 6, and the first wiring layer 16 is shown in FIG. 3. Furthermore, a graph describing a relation between the Ti film thickness of the respective top layers of the Ti/Pt/Au/Ti electrodes 6a and 7a and a size of the electrode-first wiring interlayer contact hole 15 is shown in FIG. 4.

From FIG. 3, it can be understood that when the Ti film thickness of the respective top layers of the Ti/Pt/Au/Ti electrodes 6a and 7a is smaller than 5 nm, the contact resistance dramatically rises. Moreover, from FIG. 4, it can be understood that when the Ti film thickness of the respective top layers of the Ti/Pt/Au/Ti electrodes 6a and 7a is larger than 15 nm, size accuracy of the electrode-first wiring interlayer contact hole 15 drastically deteriorates.

As described above, according to the method for manufacturing the HBT of the present embodiment, although As frees from a region where the collector electrode 8 made of AuGe/Ni/Au is formed at the time of the heat treatment of the electrodes, since the respective top layers of the Ti/Pt/Au/Ti electrodes 6a and 7a are Ti, bonding the freed As and Pt of the Ti/Pt/Au/Ti electrodes 6a and 7a does not occur. Consequently, surface abnormality of the emitter electrode 6 or the base electrode 7 or rise of sheet resistance does not occur. Therefore, it is possible to manufacture the HBT which does not allow pattern abnormality of the electrode and deterioration of an electronic property to occur on the entire GaAs substrate.

In addition, according to the method for manufacturing the HBT of the present embodiment, almost no additional processes or materials are necessary compared to a conventional method for manufacturing the HBT. As a result, it is possible to manufacture the HBT which prevents the pattern abnormality of the electrode and the deterioration of the electronic property almost without any additional costs.

### Second Embodiment

Hereinafter, a method for manufacturing a HBT according to a second embodiment of the present invention is described with reference to the drawings.

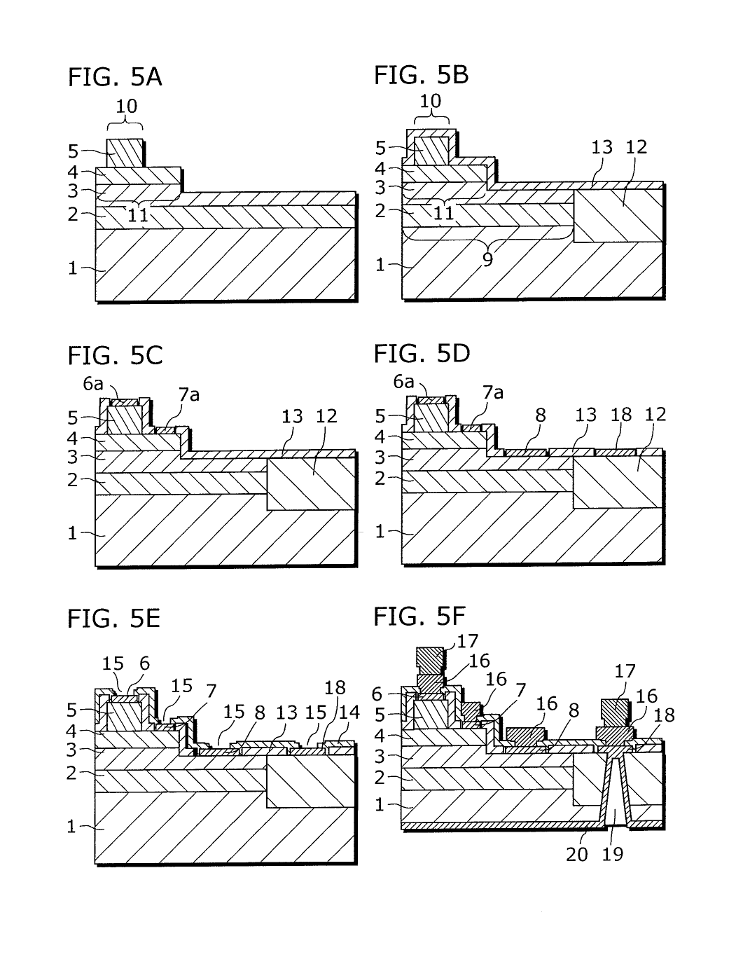

FIGS. 5A to 5F are a cross section showing each process in the method for manufacturing the HBT according to the second embodiment of the present invention.

First, the GaAs substrate (GaAs wafer) is formed by sequentially epitaxial-growing the subcollector layer 2 made of GaAs, the collector layer 3 made of GaAs, the base layer 4 made of GaAs, and the emitter layer 5 made of InGaP on the surface of the semi-insulating GaAs substrate 1. After that, the emitter mesa 10 is formed on the GaAs substrate with the photolithography method and the dry etching method, and further the base mesa 11 is formed in the same manner (FIG. 5A).

Next, the element isolation region 12 made of the high-resistivity layer is formed by performing ion implantation using the photoresist film for covering the emitter mesa 10 and the base mesa 11 as the mask, and the HBT unit cell region 9 (transistor region) is laid out. After that, the spacer film 13 made of the SiO₂ film is formed on the entire GaAs substrate (FIG. 5B).

Next, after a resist is patterned so that the hole opening is formed at the place where the Ti/Pt/Au/Ti electrodes 6a and 7a are to be formed with the photolithography method, another hole opening is formed at the hole opening of the resist on the exposed spacer film 13. Subsequently, after Ti/Pt/Au/Ti is made into a film with the vacuum evaporation method, the Ti/Pt/Au/Ti electrodes 6a and 6b which are layered, from the bottom, with Ti/Pt/Au/Ti are formed with the lift-off method (FIG. 5C).

Next, concerning a place where the collector electrode 8 and a backside via hole stopper metal 18 are to be formed, after a resist is patterned in the same manner so that a hole opening is formed, another hole opening is formed at the hole opening of the resist on the exposed spacer film 13. Subsequently, after AuGe/Ni/Au is made into a film with the vacuum evaporation method, the collector electrode 8 which is layered, from the bottom, with AuGe/Ni/Au and the backside via hole stopper metal 18 are formed with the lift-off method (FIG. 5D). The backside via hole stopper metal 18 is a metal formed on a portion where a via hole of the semi-insulating GaAs substrate 1 is to be formed so as to electrically connect a front side and a back side of the semi-insulating GaAs substrate 1. The backside via hole stopper metal 18 prevents a backside electrode metal 20 from flowing out, via the via hole, to the front side of the semi-insulating GaAs substrate 1 at a time of formation of the backside electrode metal 20.

Next, in a state where the Ti/Pt/Au/Ti electrodes 6a and 7a, the collector electrode 8, and the backside via hole stopper metal 18 are not covered with an interlayer film respectively, that is, in a state where each of them is exposed to the surface, the heat treatment at 380° C. for 90 seconds is performed on each of the electrodes and the backside via hole stopper metal 18. It should be noted that, from the point of view of suppressing the free of As as much as possible and of reducing the contact resistance among the base electrode 7, the emitter electrode 6, and the first wiring layer 16, in the processing of the heat treatment, as long as the treatment temperature at the time of the heat treatment and the treatment time are optimized between 360° C. and 420° C. and between 15 seconds and 360 seconds respectively, the heat treatment condition may not be 380° C. and 90 seconds.

Next, a SiN film is formed, as the first interlayer film 14, on the entire GaAs substrate with the plasma CVD method. Subsequently, the electrode-first wiring interlayer contact hole 15 is formed by removing, with the dry etching method, a part of the first interlayer film 14 where the Ti/Pt/Au/Ti electrodes 6a and 7a, the collector electrode 8, and the backside via hole stopper metal 18 are to be connected to the first wiring layer 16 as the lead wiring (FIG. 5E). A dry etching process condition in a process of forming the electrode-first wiring interlayer contact hole 15 is optimized, and Ti of the respective top layers of the Ti/Pt/Au/Ti electrodes 6a and 7a is also removed concurrently with the formation of the electrode-first wiring interlayer contact hole 15. Accordingly, the emitter electrode 6 and the base electrode 7 whose partial Ti of the respective top layers is removed so as to expose Au to a surface are formed, the emitter electrode 6 and the base electrode 7 being made of Ti/Pt/Au/Ti.

Next, the first wiring layer 16 and the second wiring layer 17 are formed at a predetermined place with the well-known method.

Finally, after the semi-insulating GaAs substrate 1 is polished to 100 um and a backside via hole 19 is formed at a predetermined place with the dry etching method, the backside electrode metal 20 is formed on the back side of the semi-insulating GaAs substrate 1 with the plating method (FIG. 5F).

It should be noted that, from the point of view of the contact resistance among the base electrode 7, the emitter electrode 6, and the first wiring layer 16 and of the size controllability of the electrode-first wiring interlayer contact hole 15, it is necessary to set, between 5 nm and 15 nm, a Ti film thickness of the respective top layers of the Ti/Pt/Au/Ti electrodes 6a and 7a which are layered, from the bottom, Ti/Pt/Au/Ti. Similar to the first embodiment, the Ti film thickness is assumed to be 10 nm in the present embodiment.

As described above, according to the method for manufacturing the HBT of the present embodiment, although As frees from an AuGe/Ni/Au electrode region having a large area, such as the backside via hole stopper metal 18, at the time of the heat treatment of the electrodes, since the respective top layers of the Ti/Pt/Au/Ti electrodes 6a and 7a are Ti, bonding the freed As and Pt of the Ti/Pt/Au/Ti electrodes 6a and 7a does not occur. Consequently, the surface abnormality of the emitter electrode 6 or the base electrode 7 or the rise of sheet resistance does not occur. Therefore, it is possible to manufacture the HBT which does not allow the pattern abnormality of the electrode and the deterioration of the electronic property to occur on the entire GaAs substrate.

Furthermore, according to the method for manufacturing the HBT of the present embodiment, almost no additional processes or materials are necessary compared to the conventional method for manufacturing the HBT. Accordingly, it is possible to manufacture the HBT which prevents the pattern abnormality of the electrode and the deterioration of the electronic property almost without any additional costs.

Although the method for manufacturing the semiconductor device of the present invention is described based on the embodiments, the present invention is not limited to the embodiments. A scope of the present invention includes a wide variety of modifications within the gist of the present invention made by a person with an ordinary skill in the art.

For example, the HBT is exemplified as the semiconductor device of the present invention. However, as long as a semiconductor device includes a semiconductor substrate having a portion made of GaAs, an AuGe/Ni/Au electrode directly contacting GaAs of the semiconductor substrate, and a Ti/Pt/Au electrode, and performs the heat treatment on the AuGe/Ni/Au electrode in a state where both of the electrodes are not covered with the interlayer film, the present invention is not limited to this semiconductor device and may be other devices, such as a field-effect transistor (FET) and the like.

Moreover, although the Ti/Pt/Au/Ti electrode is exemplified as the first electrode of the present invention, as long as an electrode includes Pt and has a layered structure in which the top layer is Ti, the present invention is not limited to such electrode.

Further, although the collector electrode made of AuGe/Ni/Au is exemplified as the second electrode of the present invention, as long as an electrode includes AuGe contacting GaAs which makes of the HBT, the present invention is not limited to such electrode.

And further, although the GaAs substrate is exemplified as the semiconductor substrate of the present invention, as long as a semiconductor substrate has a portion made of GaAs, the present invention is not limited to such semiconductor substrate.

### INDUSTRIAL APPLICABILITY

The present invention is useful as the method for manufacturing the semiconductor, and particularly as the method for manufacturing the semiconductor device operating in the high frequency band.

What is claimed is:

1. A method for manufacturing a semiconductor device which includes a semiconductor substrate having a portion made of GaAs, said method comprising:
forming a first electrode on the semiconductor substrate, the first electrode including Pt and having a layered structure in which a top layer is made of Ti;
forming a second electrode including AuGe on the portion made of GaAs; and
performing heat treatment on the second electrode in a state where the first electrode and the second electrode are exposed to a surface.

2. The method for manufacturing the semiconductor device according to claim 1,
wherein, in said forming of the first electrode, the first electrode having the top layer of Ti is formed, the top layer having a film thickness between 5 nm and 15 nm inclusive.

3. The method for manufacturing the semiconductor according to claim 1,
wherein, in said forming of the second electrode, a backside via hole stopper metal is formed on the semiconductor substrate concurrently with the formation of the first electrode.

4. The method for manufacturing the semiconductor device according to claim 1,
wherein, in said performing of the heat treatment, the heat treatment is performed at a temperature between 360° C. and 420° C. inclusive.

5. The method for manufacturing the semiconductor device according to claim 4, further comprising:
forming an interlayer film on both of the first electrode and the second electrode after performing the heat treatment; and
removing a part of the interlayer film in order to connect both of the first electrode and the second electrode to a lead wiring.

6. The method for manufacturing the semiconductor device according to claim 5,
wherein, in said removing, the top layer of Ti of the first electrode is removed concurrently with the removing of the part of the interlayer film.

7. The method for manufacturing the semiconductor device according to claim 6,
wherein the semiconductor device is a heterojunction bipolar transistor.

8. The method for manufacturing the semiconductor device according to claim 6,
wherein the semiconductor device is a field-effect transistor.

9. The method for manufacturing the semiconductor device according to claim 1, further comprising:
forming an interlayer film on both of the first electrode and the second electrode after performing the heat treatment; and
removing a part of the interlayer film in order to connect both of the first electrode and the second electrode to a lead wiring.

10. The method for manufacturing the semiconductor device according to claim 1,
wherein the semiconductor device is a heterojunction bipolar transistor.

11. The method for manufacturing the semiconductor device according to claim 1,
wherein the semiconductor device is a field-effect transistor.
